(19) United States
(12) Patent Application Publication
(10) Pub. No.: US 2014/0001940 A1
(43) Pub. Date: Jan. 2, 2014

(54) ENCLOSURE OF ELECTRONIC DEVICE

(71) Applicants: SHENG-TIEN CHANG, Tu-Cheng (TW); CHIN-MING CHEN, Tu-Cheng (TW); CHING-JOU CHEN, Tu-Cheng (TW); WEN-CHIN LIN, Tu-Cheng (TW); WEN-CHIEH WANG, Tu-Cheng (TW)

(72) Inventors: SHENG-TIEN CHANG, Tu-Cheng (TW); CHIN-MING CHEN, Tu-Cheng (TW); CHING-JOU CHEN, Tu-Cheng (TW); WEN-CHIN LIN, Tu-Cheng (TW); WEN-CHIEH WANG, Tu-Cheng (TW)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/558,355

(22) Filed: Jul. 26, 2012

(30) Foreign Application Priority Data
Jun. 27, 2012 (CN) 2012102150682

(51) Int. Cl. H05K 5/02

(52) U.S. Cl. 312/326

(57) ABSTRACT

An enclosure includes a chassis, a front panel pivotably attached to the chassis, a latching member movably attached to the front panel for latching the front panel to the chassis, and a controlling apparatus. The controlling apparatus utilizes a connecting pole to engage with or disengage from the latching member, to control the latching member to be locked to the chassis or released from the chassis.

### BACKGROUND

1. Technical Field

The present disclosure relates to an enclosure of an electronic device.

2. Description of Related Art

An enclosure of an electronic device often includes a removable side plate, which is locked to the enclosure through a padlock, to prevent theft of the electronic components in the enclosure. When needing to repair or replace the hard disk drives, it is inconvenient to repeatedly unlock and lock the side plate to the enclosure. Another type of enclosure includes a front panel which is unlocked can be conveniently opened to repair or replace the hard disk drives. However, the unlocked front panel leaves the electronic components in the electronic device unsecure.

### BRIEF DESCRIPTION OF THE DRAWINGS

Many aspects of the present embodiments can be better understood with reference to the following drawings. The components in the drawing are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled, isometric view of an enclosure in accordance with an exemplary embodiment, wherein the enclosure includes a chassis, a front panel pivotably attached to the chassis, and a controlling apparatus.

FIG. 2 is similar to FIG. 1, but viewed from another aspect and showing the front panel opened.

FIG. 3 is an exploded, isometric view of the items of FIG. 2.

FIG. 4 is an exploded, isometric view of the items of FIG. 1, but showing the front panel opened.

FIG. 5 is an assembled, isometric view of the items of FIG. 4.

FIG. 6 is an exploded, isometric view of one part of the controlling apparatus of FIG. 1.

FIG. 7 is an assembled, isometric view of the items of FIG. 6, but shows the controlling apparatus unlocked.

FIG. 8 is a partially assembled view of the items of FIG. 6, but viewed from another aspect.

FIG. 9 is an assembled, isometric view of the items of FIG. 6, but shows the controlling apparatus in a locked state.

### DETAILED DESCRIPTION

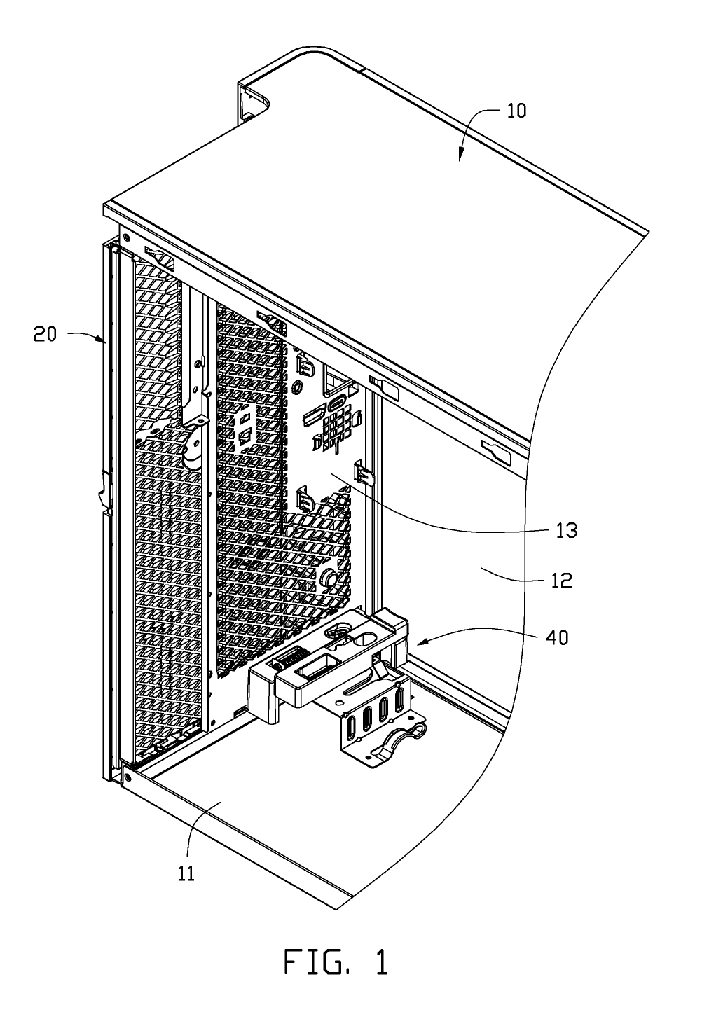

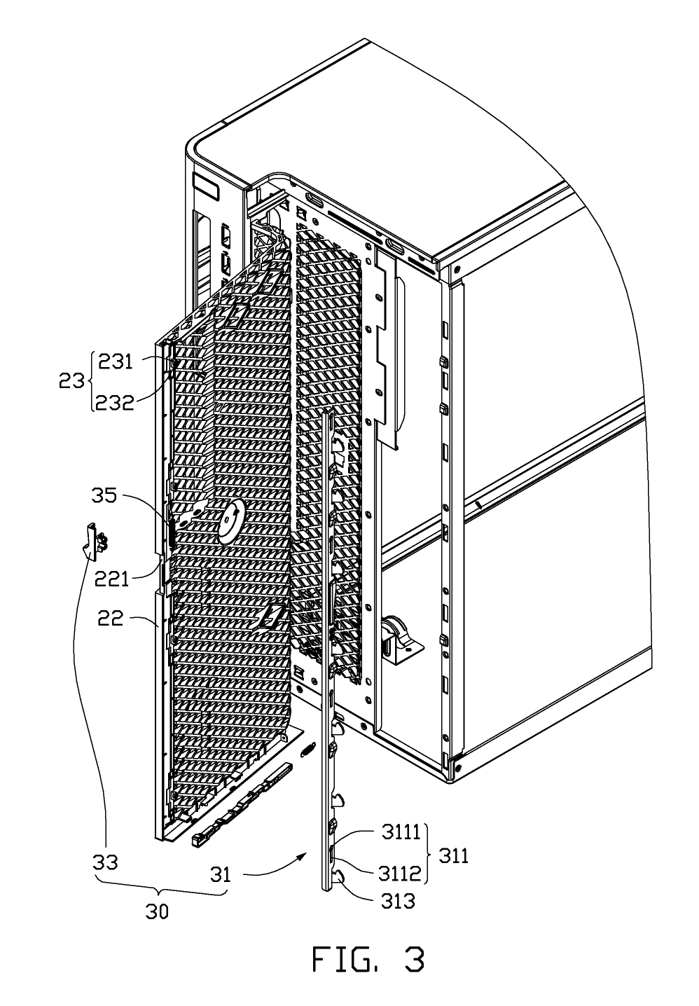

Referring to FIG. 1 to FIG. 3, an embodiment of an enclosure includes a chassis 10, a front panel 20 pivotably attached to a front end of the chassis 10, a latching member 30, and a controlling apparatus 40.

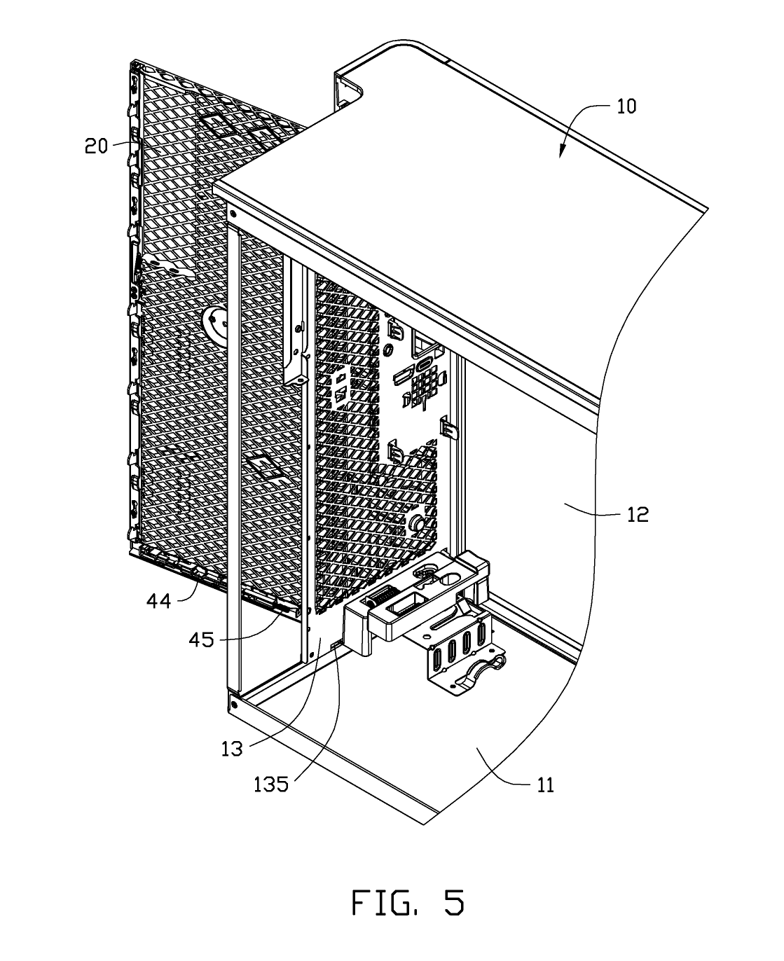

The chassis 10 includes a bottom wall 11, a sidewall 12 extending from a first side of the bottom wall 11, and a front wall 13 extending from a front end of the bottom wall 11. The front wall 13 includes a first side 131 adjacent to the sidewall 12, and a second side 132 opposite to the first side 131. The second side 132 defines an opening 133, through which access to a plurality of hard disk drives (not shown) in the chassis 10 can be taken. The front wall 13 defines a through hole 135 in a bottom portion (as shown in FIG. 5).

The front panel 20 is pivotably connected to an outer surface of the first side 131. The front panel 20 covers the opening 133. The front panel 20 includes a latching side 22, which can be latched to the second side 132. A flange 21 extends inward from a bottom of the front panel 20. A tab 211 extends from a side of the flange 21 away from the latching side 22.

The latching member 30 is slidably mounted to the latching side 22. The latching member 30 includes a latching pole 31 and a button 33 fixed to a middle of the latching pole 31. A plurality of twist-clips 23 is formed on an inner surface of the latching side 22. Each twist-clip 23 includes a neck portion 232 extending from the latching side 22, and a head portion 231 formed on a distal end of the neck portion 232. The latching pole 31 longitudinally defines a plurality of slots 311 each including a first end 3111 and a second end 3112 communicating with the first end 3111. The first end 3111 of each slot 311 has a larger width than the second end 3112. The head portions 231 can pass through the first ends 3111. The latching pole 31 is then slid up to engage the neck portions 232 in the second ends 3112. A spring 35 is arranged between the latching pole 31 and the latching side 22, to provide elastic force on the latching pole 31 to maintain the engagement of the neck portions 232 in the second ends 3112. The latching pole 31 includes a plurality of hooks 313 facing the front wall 13. The latching side 22 defines a cutout 221. The button 33 extends out of the front panel 20 through the cutout 221.

The second side 132 defines a plurality of locking holes 1321, corresponding to the hooks 313. When the front panel 20 is to be locked, the button 33 is manipulated down. The front panel 20 is rotated to the front wall 13, until the hooks 313 extend through the locking holes 1321. The button 33 is released. The spring 35 draws up the latching pole 31 to make the hooks 313 lock to an inner surface of the front wall 13. Thereby the front panel 20 is locked to the front wall 13, to cover the opening 133. To unlock the front panel 20, the button 33 is manipulated down, until the hooks 313 disengage from the locking holes 1321. The front panel 20 is then rotated away from the front wall 13, to uncover the opening 133.

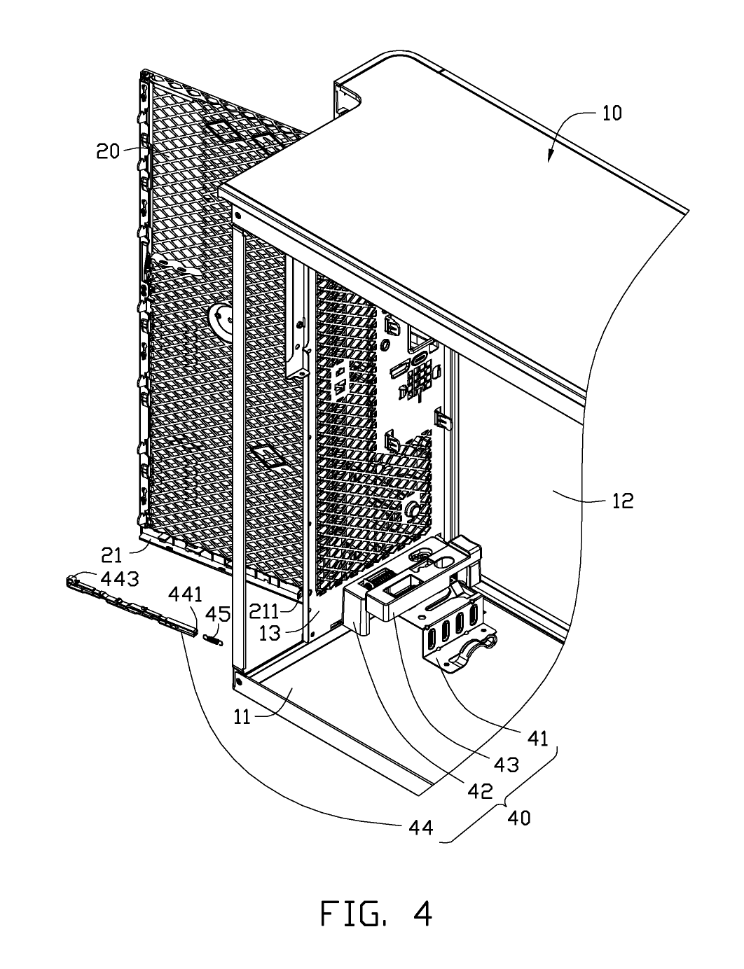

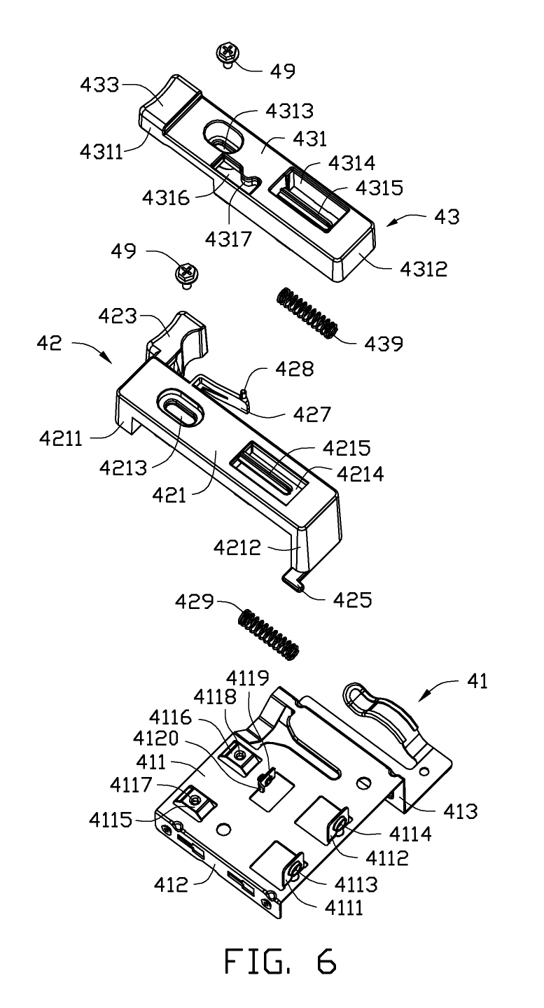

Referring to FIG. 4 to FIG. 6, the controlling apparatus 40 includes a mounting member 41 fixed on the bottom wall 11 adjacent to the front wall 13, a locking member 42 and an unlocking member 43 being both slidably attached to the mounting member 41, and a connecting pole 44.

The mounting member 41 includes a main plate 411, a first supporting plate 412, and a second supporting plate 413. The first supporting plate 412 and the second supporting plate 413 extend down from opposite ends of the main plate 411. The first supporting plate 412 is fixed on the front wall 13. The second supporting plate 413 is fixed on the bottom wall 11. A first tab 4111 defining a first through hole 4113 and a second tab 4112 defining a second through hole 4114 extend up from a first side of the main plate 411. A first raised portion 4115 defining a first mounting hole 4117 and a second raised portion 4116 defining a second mounting hole 4118 are formed on a second side of the main plate 411. A blocking piece 4119 is formed on the main plate 411 between the second tab 4112 and the second raised portion 4116. The blocking piece 4119 includes a guiding portion 4120 extending from an end of the blocking piece 4119.

The locking member 42 includes a main body 421, a pressing portion 423 extending from a first end 4211 of the main body 421, a driving portion 425 extending from a bottom of a second end 4212 of the main body 421, and a resilient positioning portion 427 extending slantwise from a side of the main body 421. A pin 428 extends from a distal end of the positioning portion 427. The main body 421 defines an elongated first slide slot 4213 adjacent to the first end 4211 and an elongated slot 4214 adjacent to the second end 4212. A first pole 4215 extends toward the second end 4212 from one sidewall bounding the slot 4214.

The unlocking member 43 includes a main body 431 and a pressing portion 433 extending from a first end 4311 of the main body 431. The main body 431 defines an elongated second slide slot 4313 adjacent to the first end 4311 and an elongated slot 4314 adjacent to a second end 4312 of the main body 431. A second pole 4315 extends toward the second end 4312 from one sidewall bounding the slot 4314. The main body 431 defines a through hole 4316 in a middle. An arc-shaped releasing portion 4317 is formed on a sidewall bounding the through hole 4316.

The connecting pole 44 includes a driven portion 441 and a blocking portion 443. The flange 21 forms a plurality of limiting portions (not labeled) to slidably assemble the connecting pole 44 to the flange 21. A spring 45 is connected between the tab 211 and the driven portion 441.

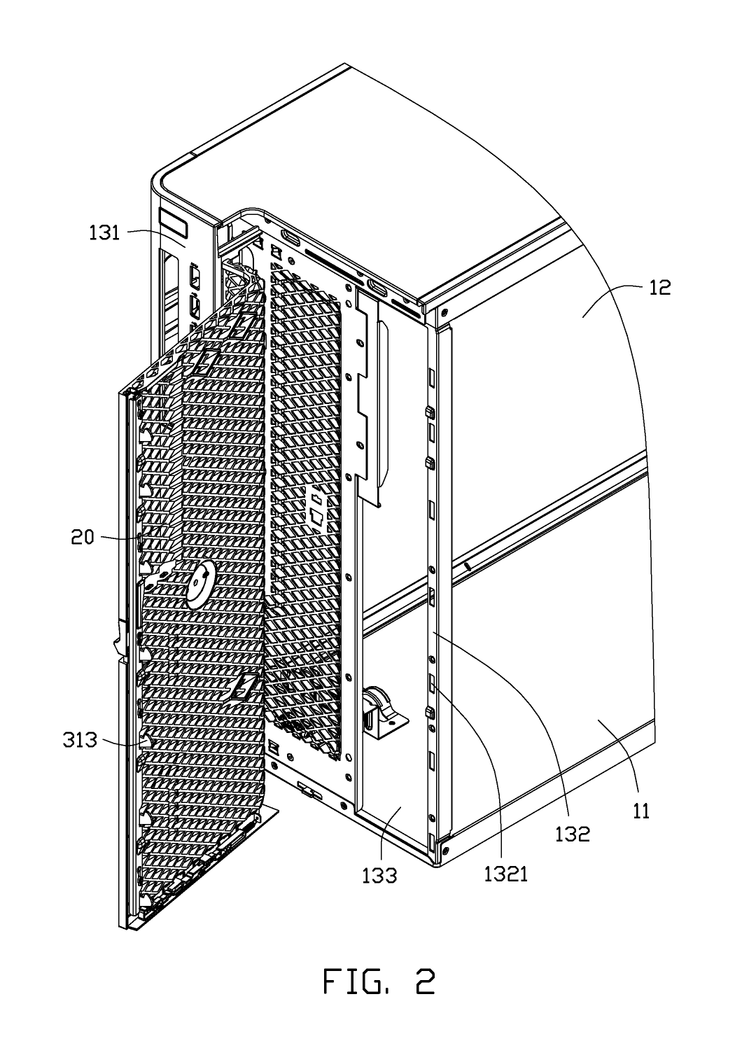

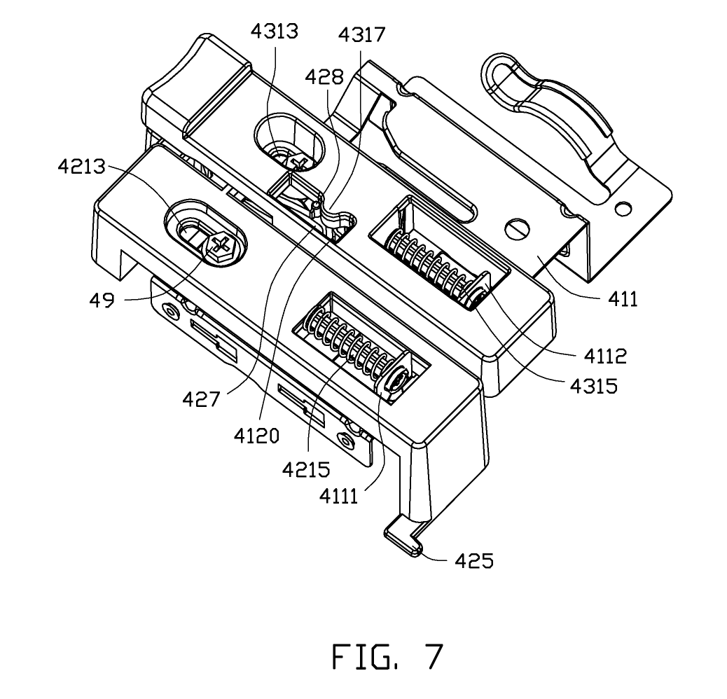

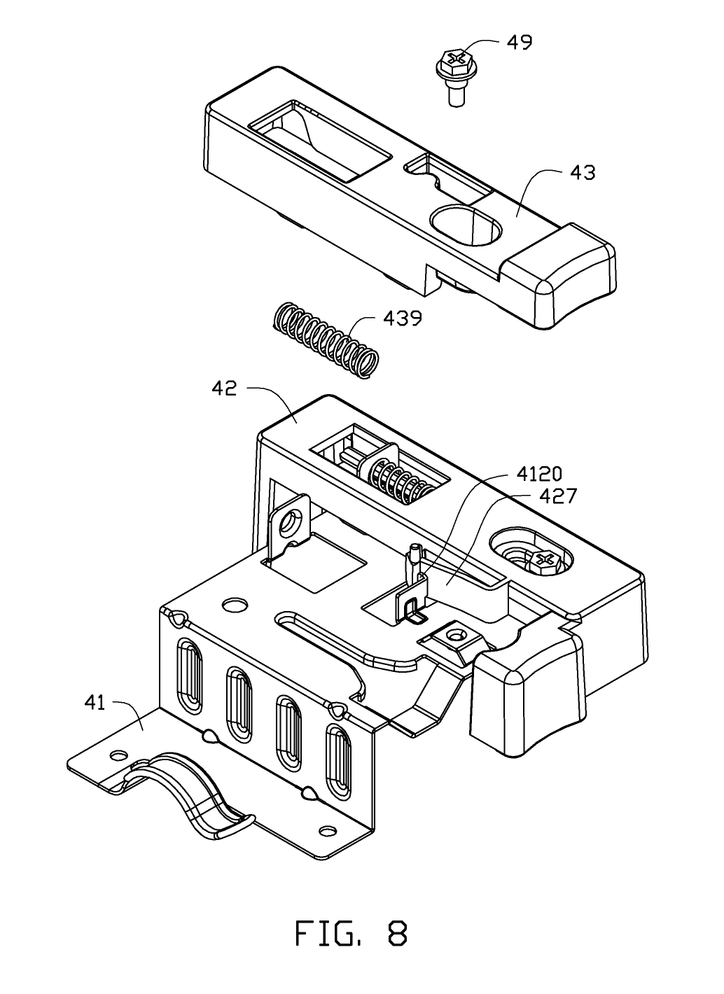

Referring to FIG. 7 and FIG. 8, when assembling the controlling apparatus 40, a first spring 429 is set around the first pole 4215. The first tab 4111 is inserted in the slot 4214 from a bottom of the locking member 42. The first pole 4215 extends through the first through hole 4113. One end of the first spring 429 abuts against the first tab 4111. A screw 49 slidably extends through the first slide slot 4213 to be screwed into the first mounting hole 4117, to slidably mount the locking member 42 to the mounting member 41. A second spring 439 is set around the second pole 4315. The second tab 4112 is inserted in the slot 4314 from a bottom of the unlocking member 43. The second pole 4315 extends through the second through hole 4114. One end of the second spring 439 abuts against the second tab 4112. A screw 49 slidably extends through the second slide slot 4313 to be screwed into the second mounting hole 4118, to slidably mount the unlocking member 43 to the mounting member 41. The positioning portion 427 is located under the unlocking member 43. The pin 428 extends through the through hole 4316. The driving portion 425 extends through the through hole 135 to engage with the driven portion 441 (referring to FIG. 1 and FIG. 2).

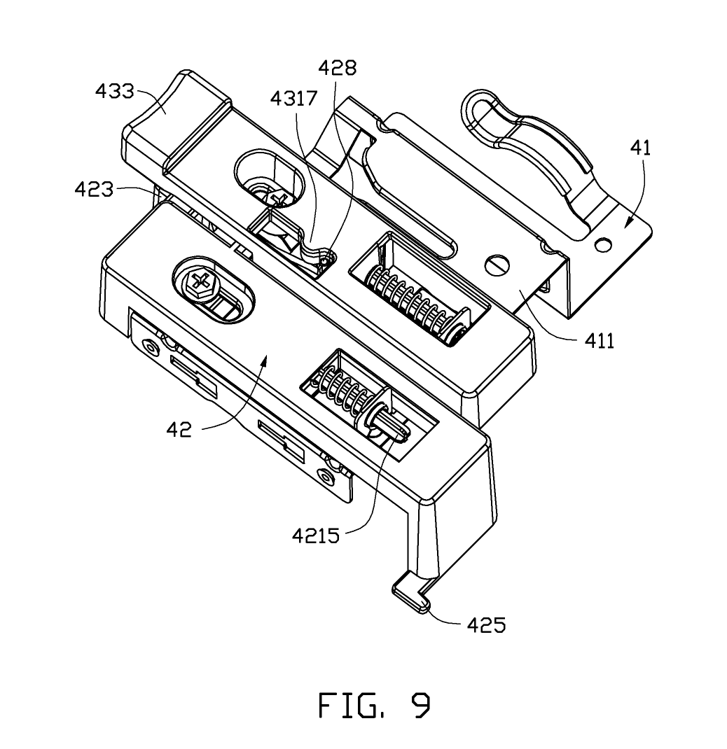

The pressing portion 423 is pressed to slide the locking member 42 relative to the mounting member 41, until the positioning portion 427 rides over the guiding portion 4120 to be locked to the blocking piece 4119. The driving portion 425 drives the driven portion 441 to move the connecting pole 44 toward the latching side 22 against the spring 45, until the blocking portion 443 is located under the latching pole 31. In this state, the button 33 cannot be pressed to move down the latching pole 31, thus the hooks 313 cannot disengage from the front wall 13, and the front panel 20 cannot be swung open from the chassis 10. The pin 428 is located under the releasing portion 4317 in this state (as shown in FIG. 9).

When the pressing portion 433 is pressed to slide the unlocking member 43 relative to the mounting member 41, the releasing portion 4317 abuts against the pin 428 to deform the positioning portion 427 towards the main body 421, until the positioning portion 427 is released from the blocking piece 4119. The first spring 429 is restored to drive the locking member 42 to slide toward the first tab 4111. The driving portion 425 then disengages from the driven portion 441. In this state, the button 33 can be pressed to move the latching pole 31 down until the hooks 313 are released from the front wall 13. Then the front panel 20 can be opened.

In this embodiment, the latching member 30 latches the front panel 20 to the chassis 10. The controlling apparatus 40 is able to control the latching member 30 to be in a locked or an unlocked state. When the latching member 30 is in the locked state, the front panel 20 cannot be opened, thus the electronic components in the chassis 10 are not dangerously exposed. When the latching member 30 is in the unlocked state, the front panel 20 can be opened, to expose the opening 133 for repairing or replacing the electronic components in the chassis 10.

Even though numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. An enclosure, comprising:
a chassis;
a front panel pivotably attached to the chassis;
a latching member slidably attached to the front panel and latching the front panel to the chassis; and
a controlling apparatus comprising a connecting pole, wherein the controlling apparatus is operated to drive the connecting pole to engage with or disengage from the latching member to retain the latching member in a locked state or an unlocked state.

2. The enclosure as claimed in claim 1, wherein the controlling apparatus further comprises a mounting member mounted in the chassis, a locking member movably mounted on the mounting member, the locking member comprises a driving portion engaging with the connecting pole, and a positioning portion locked to the mounting member to retain the driving portion engaging with the connecting pole.

3. The enclosure as claimed in claim 2, wherein the controlling apparatus further comprises an unlocking member movably mounted on the mounting member adjacent to the locking member, the unlocking member comprises a releasing portion to release the positioning portion from the mounting member.

4. The enclosure as claimed in claim 3, wherein a spring is connected between the locking member and the mounting member to move the locking member to disengage the driving portion from the connecting pole.

5. The enclosure as claimed in claim 3, wherein a blocking piece is formed on the mounting member to position the positioning portion, a pin extends from a distal end of the positioning portion, the unlocking member defines a through hole, the releasing portion is arc-shaped and extends from a sidewall bounding the through hole, the pin extends through the through hole, the unlocking member is moved, the releasing portion abuts against the pin to deform the positioning portion until the positioning portion is unlocked from the blocking piece.

6. The enclosure as claimed in claim 1, wherein the front panel comprises a flange formed from a bottom portion of the front panel, the chassis comprises a front wall defining a through hole, the connecting pole is slidably attached to the flange, the controlling apparatus comprises a driving portion extending through the through hole to engage with the connecting pole.

7. The enclosure as claimed in claim 6, wherein the connecting pole comprises a driven portion engagable with the driving portion and a blocking portion engagable with the latching member, a tab extends from the flange, a spring is connected between the tab and the driven portion.

8. The enclosure as claimed in claim 1, wherein the chassis comprises a front wall defining a locking hole, the latching member comprises a latching pole, the latching pole comprises a hook extending through the locking hole to latch to an inner surface of the front wall.

9. The enclosure as claimed in claim 8, wherein a spring is connected between the latching pole and the front panel, to provide elastic force on the latching pole to maintain the hook being locked to the inner surface of the front wall.

10. The enclosure as claimed in claim 9, wherein the connecting pole comprises a blocking portion to be located under the latching pole, the latching pole is unable to slide down to release the hook from the locking hole.

11. An enclosure, comprising:
a chassis comprising a bottom wall and a front wall extending from a front end of the bottom wall, wherein the front wall comprises a first side and a second side, an opening is defined in the front wall adjacent to the second side;
a front panel pivotably attached to the first side of the front wall and comprising a latching side;
a latching member slidably attached to the latching side of the front panel and latching the latching side of the front panel to the second side of the front wall, to make the front panel cover the opening;
a connecting pole slidably attached to the front panel; and
a locking member slidably mounted in the chassis, wherein the locking member is movable to drive the connecting pole to engage with the latching member to retain the latching member being locked to the second side of the front wall.

12. The enclosure as claimed in claim 11, wherein a mounting member is mounted in the chassis, the locking member is movably mounted on the mounting member, the locking member comprises a driving portion engaging with the connecting pole, and a positioning portion locked to the mounting member to retain the driving portion engaging with the connecting pole.

13. The enclosure as claimed in claim 12, wherein an unlocking member is movably mounted on the mounting member adjacent to the locking member, the unlocking member comprises a releasing portion to release the positioning portion from the mounting member.

14. The enclosure as claimed in claim 13, wherein a spring is connected between the locking member and the mounting member to move the locking member to disengage the driving portion from the connecting pole.

15. The enclosure as claimed in claim 13, wherein a blocking piece is formed on the mounting member to position the positioning portion, a pin extends from a distal end of the positioning portion, the unlocking member defines a through hole, the releasing portion is arc-shaped and extends from a sidewall bounding the through hole, the pin extends through the through hole, the unlocking member is moved, the releasing portion abuts against the pin to deform the positioning portion until the positioning portion is unlocked from the blocking piece.

16. The enclosure as claimed in claim 11, wherein the front panel comprises a flange formed from a bottom portion of the front panel, the front wall defines a through hole, the connecting pole is slidably attached to the flange, the locking member comprises a driving portion extending through the through hole to engage with the connecting pole.

17. The enclosure as claimed in claim 16, wherein the connecting pole comprises a driven portion engagable with the driving portion and a blocking portion engagable with the latching member, a tab extends from the flange, a spring is connected between the tab and the driven portion.

18. The enclosure as claimed in claim 11, wherein the second side of the front wall defines a locking hole, the latching member comprises a latching pole, the latching pole comprises a hook extending through the locking hole to latch to an inner surface of the front wall.

19. The enclosure as claimed in claim 18, wherein a spring is connected between the latching pole and the front panel, to provide elastic force on the latching pole to maintain the hook being locked to the inner surface of the front wall.

20. The enclosure as claimed in claim 19, wherein the connecting pole comprises a blocking portion to be located under the latching pole, the latching pole is unable to slide down to release the hook from the locking hole.
